(19) United States
(12) Patent Application Publication
(10) Pub. No.: US 2019/0131247 A1
(43) Pub. Date: May 2, 2019

(54) Semiconductor Wafer Cutting Using A Polymer Coating To Reduce Physical Damage

(71) Applicant: Microchip Technology Incorporated, Chandler, AZ (US)

(72) Inventor: Man Kit Lam, Colorado Springs, CO (US)

(73) Assignee: Microchip Technology Incorporated, Chandler, AZ (US)

(21) Appl. No.: 16/043,776

(22) Filed: Jul. 24, 2018

Related U.S. Application Data
(60) Provisional application No. 62/579,524, filed on Oct. 31, 2017.

(51) Int. Cl. H01L 23/544; H01L 23/00; H01L 25/065

(52) U.S. Cl. CPC H01L 23/544; H01L 25/0655; H01L 24/94

(57) ABSTRACT

Methods for providing a polymer coating on the scribe lines of a semiconductor wafer to reduce or eliminate chipping caused by mechanical saw cutting along the scribe lines are provided. A method of forming an array of separated integrated circuit dice may include forming a plurality of integrated circuits on a semiconductor wafer, defining a scribe line on the semiconductor wafer, forming a polymer layer on the scribe line, and sawing the semiconductor wafer along the scribe line, such that the saw passes through the polymer layer and at least partially through the semiconductor wafer, to define the array of separated integrated circuit dice, wherein the polymer layer on the scribe line reduces or eliminates chipping or other physical defects in the separated integrated circuit dice resulting from the sawing process.

### RELATED PATENT APPLICATION

This application claims priority to commonly owned U.S. Provisional Patent Application No. 62/579,524 filed Oct. 31, 2017, the entire contents of which are hereby incorporated by reference for all purposes.

### TECHNICAL FIELD

The present disclosure relates to integrated circuit packages, to systems and methods for providing a polymer coating on the scribe lines of a semiconductor wafer to reduce or eliminate chipping caused by saw cutting along the scribe lines.

### BACKGROUND

Various different techniques are used to cut or separate a semiconductor wafer, e.g., to singulate a wafer into multiple discrete integrated circuit dies. One common technique involves scribing a wafer to form partial cut lines on the wafer, which introduces regions of weakness, followed by a mechanical breaking procedure to separate an array of rectangular dice for subsequent operations. This scribing may be performed by a physical device, such as a diamond tipped scribe, or using a laser, for example. The mechanical breaking of the scribed wafer often forms chips, cracks, rough or jagged edges, or other irregularities in the resulting dice.

Another common technique involves laser grooving along the scribe lines on the wafer, followed by mechanical sawing along the grooves, e.g., using a blade coated or embedded with diamond particles. This technique is often used for cutting low-k dielectric wafers, which may be too weak or brittle either for mechanical breaking or for direct sawing without a preliminary grooving or scoring. This technique typically requires multiple passes, and may generate heat affected zones. Further, the laser grooving may add significant cost.

Another technique is laser through-cut dicing, where a laser is used to cut fully through the wafer. This technique typically involves extreme temperatures, which may have negative effects on the structures, and may be expensive. Still another technique involves laser stealth dicing, which uses laser radiation at multiple frequencies to cut partially or fully through the silicon. Yet another technique involves plasma-based dicing. These techniques are typically high cost and suffer from various drawbacks, e.g., forming chips, cracks, rough or jagged edges, or other irregularities in the resulting dice, which may result in explicit or latent product reliability failures.

Any of the various wafer cutting/separation techniques may be used for both conventional IC packaging, in which the wafer is singulated into multiple discrete dice which are then individually packaged, and for Wafer Level Chip Scale Packaging (WLCSP), in which the integrated circuit is packaged at the wafer level, and then cut/singulated into a number of discrete IC packages. WLCSP is a true chip-scale packaging (CSP) technology, because the resulting package may have the same size (e.g., length and/or width dimensions) of the die. Some advantages of WLCSP include reduced die-to-PCB inductance, reduced package size, and enhanced thermal conduction characteristics.

FIGS. 1A-1C show various magnified views of example wafers that have been saw-cut into discrete dice using conventional techniques, e.g., where the scribe lines are free of polymer material, in contrast to embodiments of the present invention discussed below. FIG. 1A is a top view of a first example of a conventional saw-cut wafer 10, showing four separated dice 12, which include chipping or other physical defects D along the die edges, caused by the cutting process. FIG. 1B is a top view of a second example of a conventional saw-cut wafer 20, showing four separated dice 22, and showing a significant chip or defect D at the corner of one die. FIG. 1C shows a cross-sectional view of the chipped die 22 shown in FIG. 1B. As shown in FIGS. 1A-1C, the conventional sawing process may produce chipping or other physical defects in the resulting dice, which may result in explicit product failures or latent reliability failures.

FIG. 2 shows a representative view of an example cross-section of a Wafer-Level Chip-Scale Package (WLCSP) structure 100 for a silicon wafer (substrate) 102 near a scribe region 104 of the wafer 102, according to a conventional process. WLCSP structure 100 may include a layer stack 110 formed over the silicon wafer 102, which may have integrated circuit elements formed therein. Layer stack 110 may include a passivation layer 112, a Polymer-1 layer 114, a redistribution layer (RDL) 116, and a Polymer-2 layer 118, for example. As shown, the scribe region 104 may be free of poly material or other layers over the silicon wafer 102. In some techniques, each layer in stack 110 formed on the wafer 102, or at least each polymer layer, may be formed such that the respective layer does not extend over the scribe region 104, e.g., using conventional photolithographic techniques to pattern each respective layer. Conventionally, all polymer material is removed from the scribe region 104 for the intended purpose sawing quality control, based on the reasoning that polymer on the wafer 102 will gum-up the diamond particle matrix in the saw blade, resulting in passivation/silicon chipping and polymer lifting defects.

### SUMMARY

Embodiments of the present invention provide systems and methods for providing a polymer coating on the scribe lines of a semiconductor wafer to reduce or eliminate chipping caused by mechanical saw cutting along the scribe lines, and arrays of integrated circuit dice separated using such systems and methods. Some embodiments may provide a low-cost solution, may require low (or no) capital investment, and may provide consistent practical results.

Some embodiments apply to Wafer-Level Chip-Scale Package (WLCSP) products, which include polymer layer(s) in their structures, or copper pillar products that include polymer layer(s). In some embodiments, the existing polymer layer(s) of such structures may be used, e.g., modified, for the purpose disclosed herein, e.g., coating the wafer scribe region, to achieve the result of reducing or eliminating chipping or other physical defects causes by the sawing, and may also add little or no cost to the existing production process.

One embodiment provides a method of forming an array of separated integrated circuit dice, including forming a plurality of integrated circuits on a semiconductor wafer, defining a scribe line on the semiconductor wafer, forming a polymer layer on the scribe line, and sawing the semiconductor wafer along the scribe line, such that the saw passes through the polymer layer and at least partially through the semiconductor wafer, to define the array of separated integrated circuit dice, wherein the polymer layer on the scribe line reduces or eliminates chipping or other physical defects in the separated integrated circuit dice resulting from the sawing process.

In some embodiments, the polymer layer on the scribe line is formed during the forming of the integrated circuits on the semiconductor wafer. For example, the polymer layer on the scribe line may comprise a portion of a Poly-1 layer formed during the forming of the integrated circuits. As another example, the polymer layer on the scribe line may comprise a portion of a Poly-2 layer formed during the forming of the integrated circuits.

In one embodiment, forming a polymer layer on the scribe line includes forming at least one layer having a portion extending over the scribe line; removing the portion of the at least one layer extending over the scribe line to expose a top surface of the scribe line; and forming a polymer layer on the exposed top surface of the scribe line.

In one embodiment, forming the polymer layer on the scribe line including depositing a polymer layer over the semiconductor wafer, and using photolithographic process to pattern the polymer layer such that a portion of the polymer layer extends over the scribe line.

In one embodiment, the method includes through-cutting the semiconductor wafer via the sawing step, without performing a laser pre-grooving process.

In one embodiment, the polymer layer on the scribe line reduces vibration effects during the sawing step.

In some embodiments, the polymer layer on the scribe line has a thickness in the range of 2-20 microns, or 5-10 microns, for example, 7-8 microns.

In one embodiment, the polymer layer on the scribe line comprises polyimide (PI) or polybenzoxazole (PBO).

Another embodiment provides an array of separated integrated circuit dice formed by a process including forming a plurality of integrated circuits on a semiconductor wafer, defining a scribe line on the semiconductor wafer, forming a polymer layer on the scribe line, and sawing the semiconductor wafer along the scribe line, such that the saw passes through the polymer layer and at least partially through the semiconductor wafer, to define the array of separated integrated circuit dice, wherein the polymer layer on the scribe line reduces or eliminates chipping or other physical defects in the separated integrated circuit dice resulting from the sawing process.

### BRIEF DESCRIPTION OF THE DRAWINGS

Example aspects of the present disclosure are described below in conjunction with the figures, in which:

FIGS. 1A-1C show magnified views of example wafers that have been saw-cut into discrete dice using conventional techniques, e.g., where the scribe lines are free of polymer material;

FIG. 2 shows a representative view of an example cross-section of a Wafer-Level Chip-Scale Package (WLCSP) structure of a silicon wafer near a scribe region, according to a conventional process;

FIG. 3 shows a representative view of an example cross-section of an WLCSP structure, including a Poly-1 layer extending over a scribe region, for improving a sawing/cutting along the scribe, according to one embodiment of the present disclosure;

FIG. 4 shows a representative view of an example cross-section of an WLCSP structure, including a Poly-2 layer extending over a scribe region, for improving a sawing/cutting along the scribe, according to one embodiment of the present disclosure;

FIG. 5 shows a representative view of an example cross-section of an WLCSP structure, including Poly-1 and Poly-2 layers extending over a scribe region, for improving a sawing/cutting along the scribe, according to one embodiment of the present disclosure;

FIG. 6 shows a representative view of an example cross-section of an WLCSP structure, including a discrete polymer layer deposited over an exposed scribe region, for improving a sawing/cutting along the scribe, according to one embodiment of the present disclosure;

FIGS. 7A and 7B are top view images of an example wafer processed according to an embodiment of the present invention.

FIG. 8 shows images of side cross-sections of four example dice after being saw cut according to the techniques discussed here, e.g., using a polymer coated scribe region to improve the cutting results;

FIG. 9A shows high-magnification images of a diamond-embedded saw blade after cutting semiconductors wafers according to a conventional technique in which the scribe is uncoated by polymer; and

FIG. 9B shows high-magnification images of a diamond-embedded saw blade after cutting semiconductors wafers according to an example embodiment in which the scribe is polymer-coated.

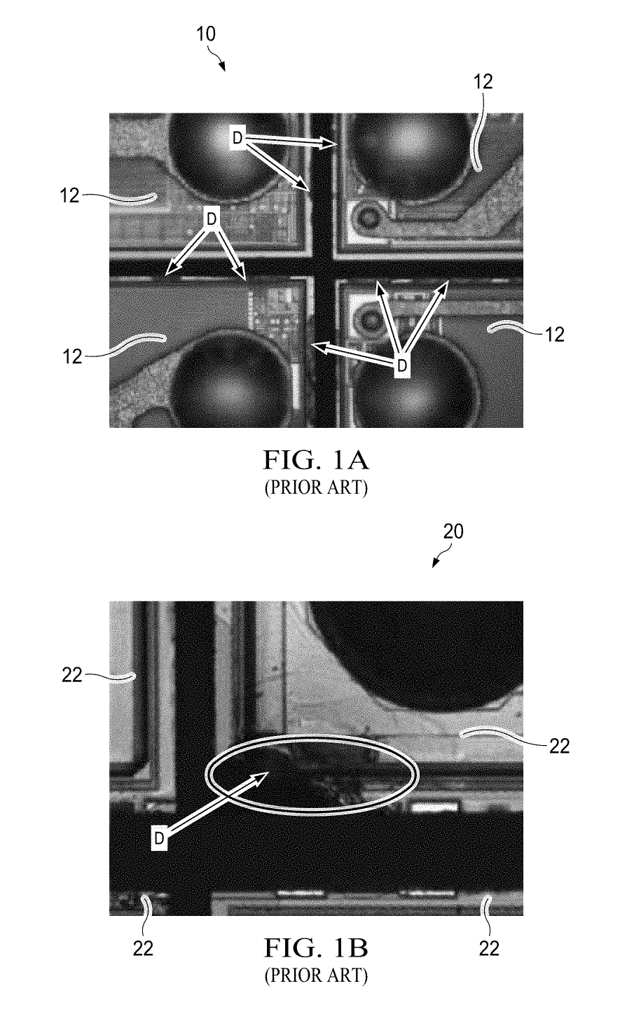

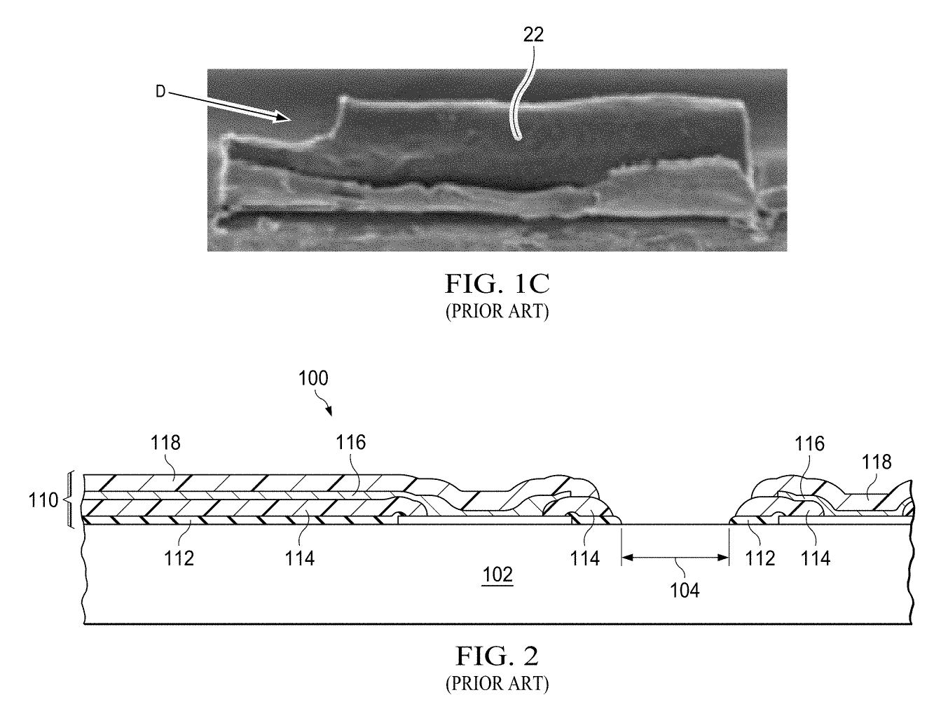

### DETAILED DESCRIPTION

Embodiments of the present disclosure may coat the scribe lines of a wafer with at least one polymer layer to help reduce or eliminate chipping caused by mechanical sawing.

Any of the concepts disclosed herein may apply to any suitable types of integrated circuit structures and products, including, as examples only, (a) Wafer-Level Chip-Scale Package (WLCSP) products, which include polymer layer(s) in their structures, and (b) copper pillar products that include polymer layer(s). In some embodiments, the existing polymer layer(s) of such structures may be used, e.g., modified, for the purpose disclosed herein, e.g., coating the wafer scribe region, to achieve the result of reducing or eliminating chipping or other physical defects causes by the sawing, and may also add little or no cost to the existing production process. Any of the disclosed concepts may also apply to other wafer products, e.g., products that do not inherently include polymer layer(s) that can be modified to extend over the wafer scribe, by adding a polymer layer over the scribe, to thereby reduce or eliminate chipping or other physical defects caused by sawing, as discussed herein.

Thus, embodiments of the present invention may reduce or eliminate chipping or other physical defects caused by mechanical sawing of the wafer. Embodiments may provide a low-cost solution, may require low (or no) capital investment, and may provide consistent practical results.

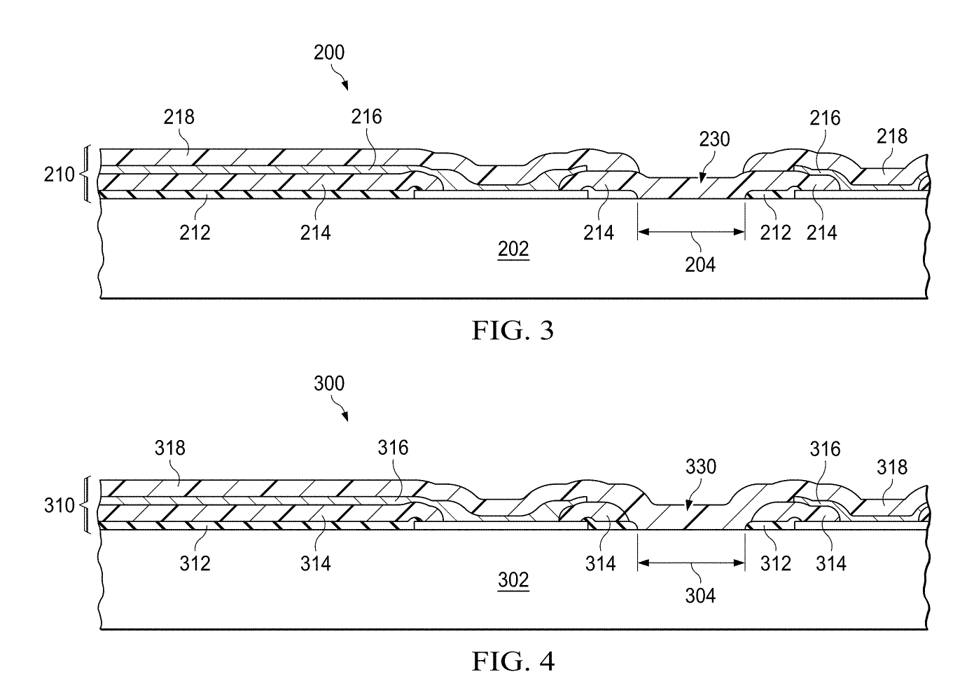

FIG. 3 shows a representative view of an example cross-section of a Wafer-Level Chip-Scale Package (WLCSP) structure 200 for a silicon wafer (substrate) 202 near a scribe region 204 of the wafer 202, according to one embodiment of the present disclosure. FIG. 3 may be compared with prior art FIG. 2, for reference. WLCSP structure 200 may include a layer stack 210 formed over the silicon wafer 202, which may have integrated circuit elements formed therein. Layer stack 210 may include a passivation layer 212, a Polymer-1 layer 214, a redistribution layer (RDL) layer 216, and a Polymer-2 layer 218, for example. However, unlike in the conventional process shown in FIG. 2, in the example embodiment shown in FIG. 3 a polymer layer Pscribe 230 is formed over the scribe region 204, e.g., to coat the wafer scribe. The polymer layer Pscribe 230 formed over the scribe region 204 may be formed in any suitable manner. For example, the polymer layer Pscribe 230 may comprise a portion of a polymer layer (e.g., polymer-1, polymer-2, etc.) formed during the formation of the layer stack 210. In the illustrated embodiment, polymer layer Pscribe 230 comprises a portion of the Polymer-1 layer 214. Thus, the Polymer-1 layer 214 may be patterned such that it extends over the scribe region 204, thereby defining the polymer region Pscribe 230, e.g., using conventional photolithographic techniques. Polymer region Pscribe 230 may be maintained in place for a subsequent cutting/sawing process along scribe 304.

The inventors have discovered that providing polymer material on the wafer scribe 204 may provide a “hold-down” effect on the stack layers and reduce vibration caused by the sawing process, which may reduce or eliminate chipping or other physical defects in the package(s).

In other embodiments, instead of the Polymer-1 layer 214, the Polymer-2 layer 218 or another polymer layer may be patterned or otherwise formed to extend over the scribe region 204, thereby defining Pscribe 230. In other embodiments, multiple polymer layers of the wafer stack 210 may be patterned or otherwise formed to extend over the scribe region 204 to define Pscribe 230. In still other embodiments, Pscribe 230 may be formed (e.g., deposited, patterned, etc.) separately from the polymer layer(s) of the wafer stack 210, e.g., after a conventional stack structure such as shown in FIG. 2 has been formed.

FIG. 4 shows a representative view of an example cross-section of a WLCSP structure 300 for a silicon wafer 302 near a scribe region 304 of the wafer 302, according to another embodiment of the present disclosure. WLCSP structure 300 may be similar to WLCSP structure 200 shown in FIG. 3, with element reference numbers 3xx shown in FIG. 4 corresponding with element reference numbers 2xx shown in FIG. 3. Thus, WLCSP structure 300 may include a layer stack 310 formed over the silicon wafer 302 and including a passivation layer 312, a Poly-1 layer 314, an RDL layer 316, and a Poly-2 layer 318, for example. In this example embodiment, Poly-2 layer 318 may be formed to extend over scribe region 304, such that a portion of Poly-2 layer 318 over scribe 304 defines a polymer region Pscribe 330, which may be maintained in place for a subsequent cutting/sawing process along scribe 304.

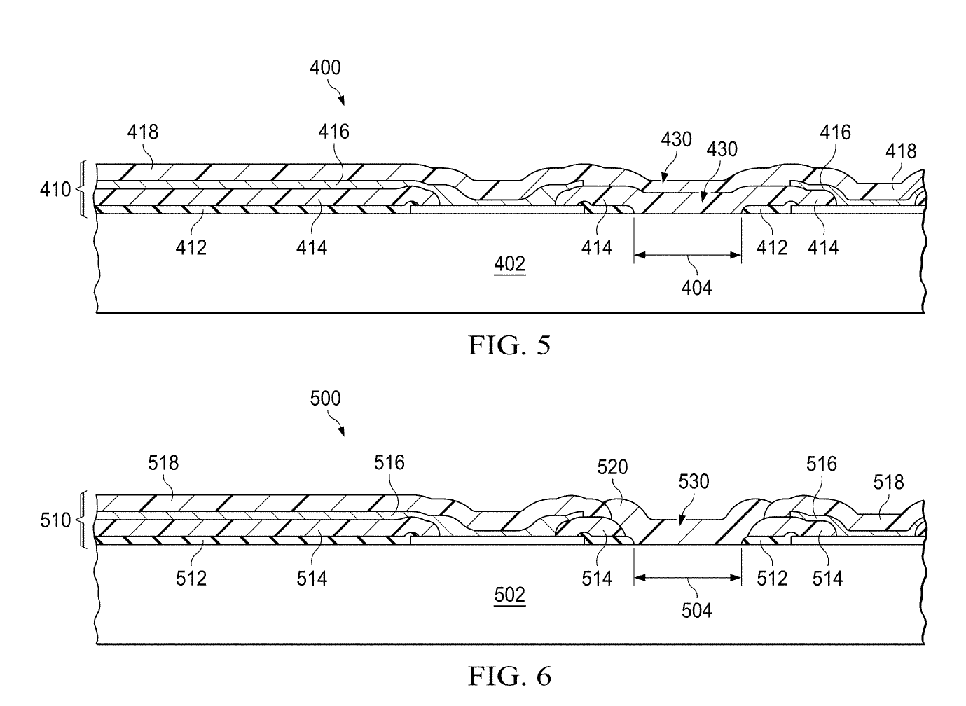

FIG. 5 shows a representative view of an example cross-section of a WLCSP structure 400 for a silicon wafer 402 near a scribe region 404 of the wafer 402, according to still another embodiment of the present disclosure. WLCSP structure 400 may be similar to WLCSP structure 200 shown in FIG. 3, with element reference numbers 4xx shown in FIG. 5 corresponding with element reference numbers 2xx shown in FIG. 3. Thus, WLCSP structure 400 may include a layer stack 410 formed over the silicon wafer 402 and including a passivation layer 412, a Poly-1 layer 414, an RDL layer 416, and a Poly-2 layer 418, for example. In this example embodiment, both Poly-1 layer 414 and Poly-2 layer 418 may be formed to extend over scribe region 404, such that respective portions of layers 414 and 418 over scribe 404 define a polymer region Pscribe 430, which may be maintained in place for a subsequent cutting/sawing process along scribe 304.

FIG. 6 shows a representative view of an example cross-section of a WLCSP structure 500 for a silicon wafer 502 near a scribe region 504 of the wafer 502, according to still another embodiment of the present disclosure. WLCSP structure 500 may be similar to WLCSP structure 200 shown in FIG. 3, with element reference numbers 5xx shown in FIG. 6 corresponding with element reference numbers 2xx shown in FIG. 3. Thus, WLCSP structure 500 may include a layer stack 510 formed over the silicon wafer 502 and including a passivation layer 512, a Poly-1 layer 514, an RDL layer 516, and a Poly-2 layer 518, for example. In this example embodiment, scribe region 504 may remain exposed after formation of stack 510, e.g., the stack layers may be formed such that they do not cover scribe 504, or alternatively one or more stack layers covering scribe 504 may be etched or otherwise removed to expose scribe region 504. A discrete polymer layer 520 may then be deposited or otherwise formed over the uncovered scribe region 504, to thereby define a polymer region Pscribe 530 covering scribe 530.

In some embodiments, a polymer coating Pscribe formed over the scribe region may include any suitable polymer material(s). For example, Pscribe may comprise or consist of polyimide (PI), polybenzoxazole (PBO), or any other suitable polymer material(s). In some embodiments, the polymer coating may have one or more selected characteristics, e.g., the Young's modulus or elastic modulus of the polymer material and/or the thickness of the polymer layer, that provide effective or desired results. For example, in some embodiments, the polymer coating may have a thickness in the range of 2-20 microns, or in the range of 5-10 microns, or about 7.5 microns (e.g., 7-8 microns).

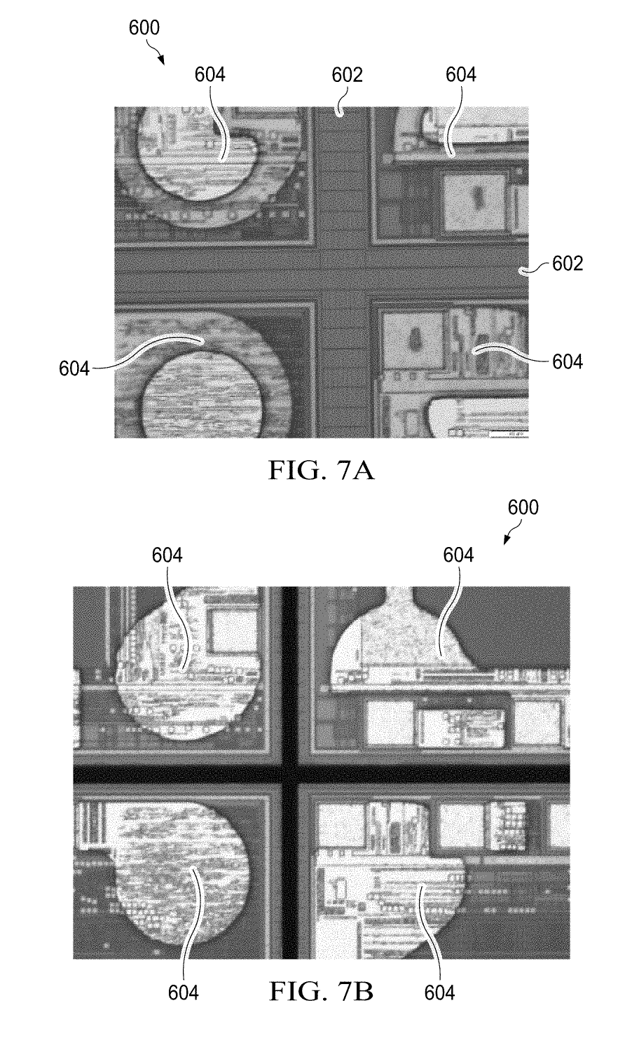

FIGS. 7A and 7B are top view images of an example wafer 600 processed according to an embodiment of the present invention. FIG. 7A shows a portion of wafer 600 having a scribe region 602 arranged between four dice 604, prior to sawing of the wafer (separation of the dice). The scribe region 602 is coated with at least one polymer layer, e.g., according to any of the example techniques discussed above. FIG. 7B shows wafer 600 after sawing along the polymer-coated scribe 602, to thereby separate the four dice 604. As shown, the edges of the cut dice 604 are linear, smooth, and free of chipping or other defects. In this example, the saw blade was used to cut 6 wafers, for a total of 205,878 dice, while showing no chipping or other defects in the cut dice throughout the process.

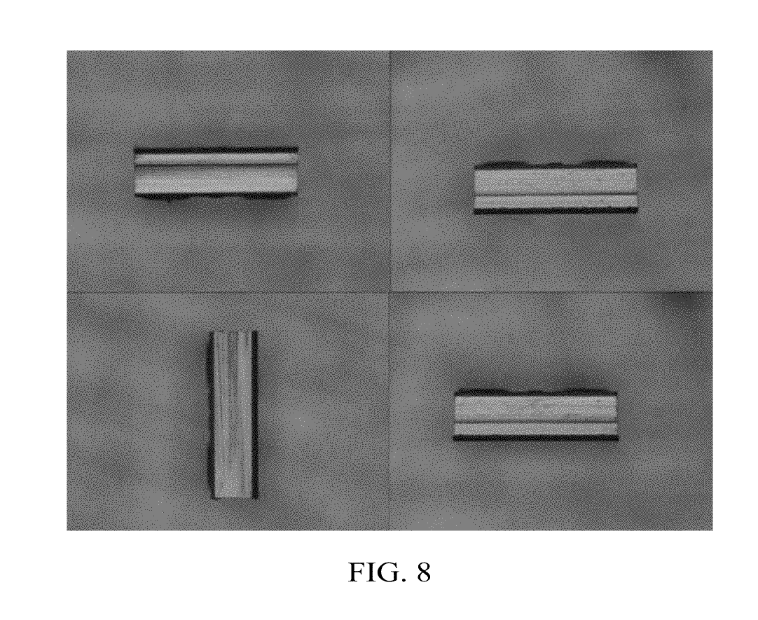

FIG. 8 shows images of side cross-sections of four example dice after being saw cut according to the techniques discussed here, e.g., using a polymer coated scribe region to improve the cutting results. As shown, the cut dice exhibit no chipping at the side walls.

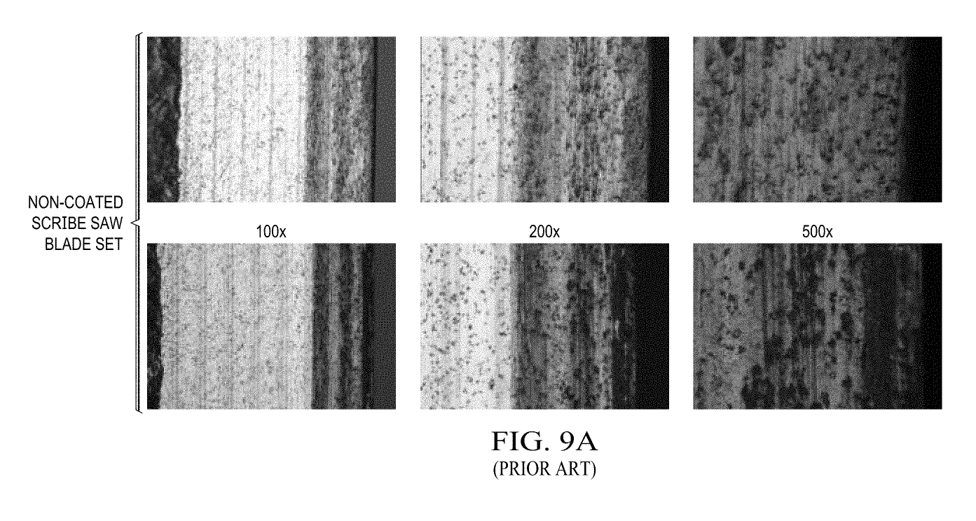

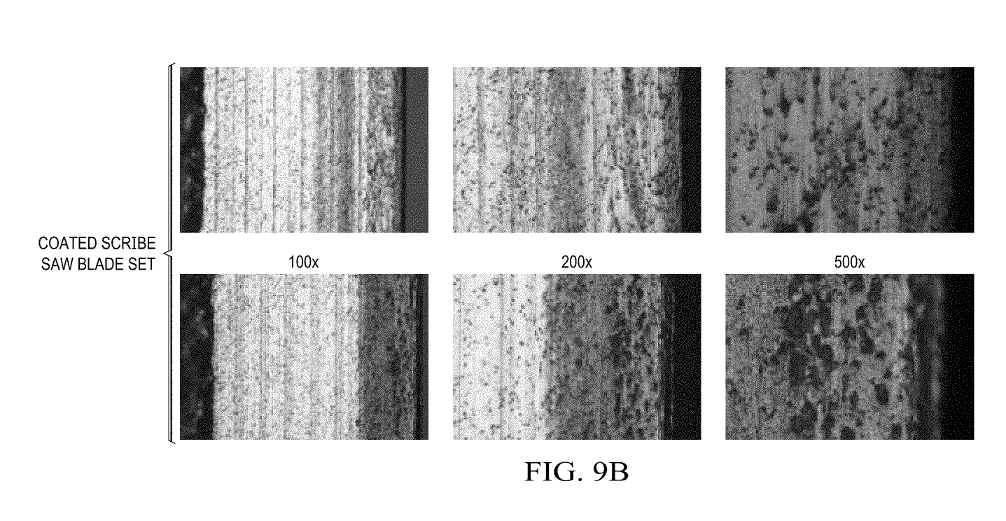

FIG. 9A shows high-magnification images, at different levels of magnification (two images at 100×, 200, and 500×), of a diamond-embedded saw blade after cutting 6 wafers (into a total of 205,878 dice) according to a conventional technique in which the scribe is uncoated by polymer. FIG. 9B shows similar high-magnification images (two images at 100×, 200, and 500×) of another example diamond-embedded saw blade after cutting 6 wafers (205,878 dice), according to an embodiment of the present invention in which the scribe is coated with polyimide (PI). As shown, the two saw blades show identical or near-identical wear rate and appearance. In addition, there is no sign of any polymer residue on the PI coated blade set shown in FIG. 9B.

Although the disclosed embodiments are described in detail in the present disclosure, it should be understood that various changes, substitutions and alterations can be made to the embodiments without departing from their spirit and scope.

What is claimed is:

1. A method of forming an array of separated integrated circuit dice, comprising:
forming a plurality of integrated circuits on a semiconductor wafer;
defining a scribe line on the semiconductor wafer;
forming a polymer layer on the scribe line; and
sawing the semiconductor wafer along the scribe line, such that the saw passes through the polymer layer and at least partially through the semiconductor wafer, to define the array of separated integrated circuit dice, wherein the polymer layer on the scribe line reduces or eliminates chipping or other physical defects in the separated integrated circuit dice resulting from the sawing process.

2. The method of claim 1, wherein the polymer layer on the scribe line is formed during the forming of the integrated circuits on the semiconductor wafer.

3. The method of claim 2, wherein the polymer layer on the scribe line comprises a portion of a Poly-1 layer formed during the forming of the integrated circuits.

4. The method of claim 2, wherein the polymer layer on the scribe line comprises a portion of a Poly-2 layer formed during the forming of the integrated circuits.

5. The method of claim 1, wherein forming a polymer layer on the scribe line comprises:
forming at least one layer having a portion extending over the scribe line;
removing the portion of the at least one layer extending over the scribe line to expose a top surface of the scribe line; and
forming a polymer layer on the exposed top surface of the scribe line.

6. The method of claim 1, wherein forming the polymer layer on the scribe line comprises:
depositing a polymer layer over the semiconductor wafer; and
using photolithographic process to pattern the polymer layer such that a portion of the polymer layer extends over the scribe line.

7. The method of claim 1, wherein the method is performed in a Wafer Level Chip Scale Packaging (WLCSP) process.

8. The method of claim 1, comprising through-cutting the semiconductor wafer via the sawing step, without performing a laser pre-grooving process.

9. The method of claim 1, wherein the polymer layer on the scribe line reduces vibration effects during the sawing step.

10. The method of claim 1, wherein the polymer layer on the scribe line has a thickness in the range of 2-20 microns.

11. The method of claim 1, wherein the polymer layer on the scribe line has a thickness in the range of 5-10 microns.

12. The method of claim 1, wherein the polymer layer on the scribe line has a thickness in the range of 7-8 microns.

13. The method of claim 1, wherein the polymer layer on the scribe line comprises polyimide (PI) or polybenzoxazole (PBO).

14. The method of claim 1, comprising sawing the semiconductor wafer using a blade coated or embedded with diamond particles.

15. An array of separated integrated circuit dice formed by a process including:
forming a plurality of integrated circuits on a semiconductor wafer;
defining a scribe line on the semiconductor wafer;
forming a polymer layer on the scribe line; and
sawing the semiconductor wafer along the scribe line, such that the saw passes through the polymer layer and at least partially through the semiconductor wafer, to define the array of separated integrated circuit dice, wherein the polymer layer on the scribe line reduces or eliminates chipping or other physical defects in the separated integrated circuit dice resulting from the sawing process.
